(19) United States
(12) Patent Application Publication
(10) Pub. No.: US 2008/0099890 A1
(43) Pub. Date: May 1, 2008

(54) Ball grid array package structure

(75) Inventors: Cheng-Pin Chen, Hukou (TW); Wen-Jeng Fan, Hukou (TW); Li-chih Fang, Hukou (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/589,155

(22) Filed: Oct. 30, 2006

(51) Int. Cl. H01L 23/495

(52) U.S. Cl. 257/666

(57) ABSTRACT

A ball grid array package structure includes: a substrate having at least one chip bearing area on its upper surface and a plurality of electrical-connecting points on its lower surface; a plurality of chips are arranged on the chip bearing area and electrically connected with those electrical-connecting points; a plurality of through holes penetrating the substrate at the edge of chip bearing area; an encapsulant used to cover those chip and filling those through holes to form a strengthened bump surrounding the chip bearing area on the lower surface of the substrate; and a plurality of conductive balls are respectively arranged on those electrical-connecting points. The present invention utilizes the strengthened bump on the bottom of the substrate to enhance the structure strength of the substrate so as to avoid the warpage of the substrate caused from the stress due to the temperature variation during the package process to affect the following processes.

### BACKGROUND OF THE INVENTION

1. Field of the Invention

The present invention relates to a semiconductor package structure and more especially, relates to a ball grid array (BGA) package structure.

2. Description of the Prior Art

Integrated Circuit (IC) assembly process is the post-term manufacturing process of the semi-conductor industry, it can identify as die saw, die bond, wire bond, mold, mark, and package, and they are mainly to separate the die of the wafer to those chips, die bond, and configure the inner lead and the outer lead, and cover the IC. The package mainly provides an interface to allow the inner electrical signal electrically connect to the system through the molding material, and the package provides the protection against the destruction from the external force, the water, the air with rich moist, or the chemical and also increases the mechanical property of the IC.

During the package process, the mold is arranged on the substrate of the semi-conductor chip or the electronic device at the beginning, and then fills the liquid molding material into the cavity of the mold to cover the chip or the electronic device to form a package with completely airtight. Then, take of the mold after harden the package to complete the package process eventually.

However, according to the development of the thin package technology, the square measure of the thin substrate is big and the depth of the substrate is thin. Due to the different coefficient of thermal expansion between the substrate and the molding material, the temperature variation will cause different distention or contraction, thus, the warpage of the substrate occurred because of the stress to affect the following processes, such as the ball mount (B/M) process, the singulation, or the temperature cycling test. Furthermore, if the warpage of the substrate is too much, the chip of the package will be cracked or the electronic device will be damaged. According to the issue mentioned previously, how to overcome the warpage of the substrate during the package process is a very important issue.

### SUMMARY OF THE INVENTION

According to the issue mentioned previously, the present invention provides a ball grid array package structure.

One of objects of this invention is to provide a strengthened bump formed by an encapsulant to improve the mechanical strength of the substrate of the ball grid array package structure.

Another object of this invention is to provide a ball grid array package structure to reduce the warpage of the substrate efficiently during the post molding cure process.

Another object of this invention is to provide a ball grid array package structure to enhance the mechanical strength of the substrate by configure a strengthened bump on the lower surface of the substrate, it can avoid the warpage of the substrate caused from the stress due to the temperature variation during the package process to affect the following processes.

Accordingly, one embodiment of the present invention provides a ball grid array package structure including a substrate, wherein the upper surface of the substrate has at least one chip bearing area, and a plurality of electrical-connecting points are configured on a lower surface; a plurality of chips are arranged on the chip bearing area and electrically connecting with those electrical-connecting points; a plurality of through holes penetrating the substrate at the edge of the chip bearing area; an encapsulant used to cover those chips and fill those through holes to form a strengthened bump surrounding the chip bearing area on the lower surface of the substrate; and a plurality of conductive balls are respectively arranged on those electrical-connecting points.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a sectional diagram of the ball grid array package structure in accordance with an embodiment of the present invention;

FIG. 2 is a bottom side view diagram of the ball grid array package structure in accordance with another embodiment of the present invention;

FIG. 3 is a bottom side view diagram of the ball grid array package structure in accordance with another embodiment of the present invention; and

FIG. 4 is a bottom side view diagram of the ball grid array package structure in accordance with another embodiment of the present invention.

### DETAILED DESCRIPTION OF THE INVENTION

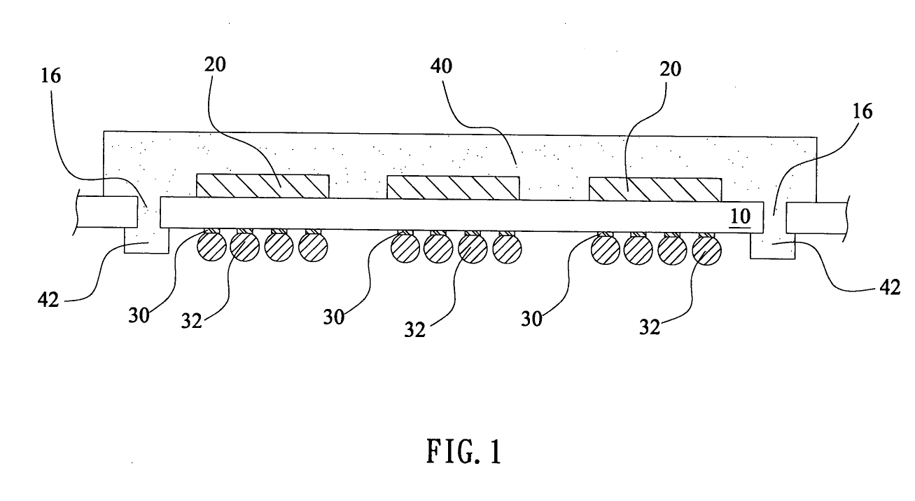

Please refer to FIG. 1, is a sectional diagram of the ball grid array package structure in accordance with an embodiment of the present invention. Shown in the figure, the BGA package structure includes a substrate 10, wherein the upper surface of the substrate 10 has at least one chip bearing area (not shown), and those electrical-connecting points 30 are arranged on the lower surface of the substrate 10; a plurality of chips 20 are arranged on the chip bearing area and electrically connected with those electrical-connecting points 30; a plurality of through holes 16 penetrate the substrate 10 at the edge of the chip bearing area; an encapsulant 40 used to cover those chips 20 and fills those through holes 16 to form a strengthened bump 42 surrounding the chip bearing area on the lower surface of the substrate 10; and a plurality of conductive balls 32 are respectively arranged on those electrical-connecting points 30.

In this embodiment, the substrate 10 is made of anyone of polyamide, glass, aluminum oxide, epoxy, beryllium oxide, or elastomer. And, the encapsulant 40 is mainly made of epoxy, the electrical-connecting point 30 is made of metal solder pad, and the conductive ball 32 is conductive stannum ball.

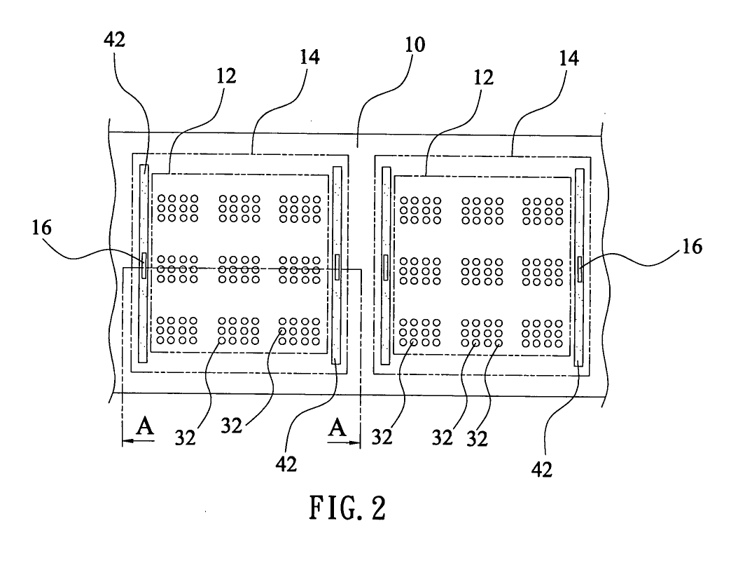

Continuously, please refer to FIG. 2, is a bottom side view diagram of the ball grid array package structure in accordance with another embodiment of the present invention and the FIG. 1 is the sectional view diagram of the portion indicated by the section lines A-A in FIG. 2. Shown in the FIG. 2, the encapsulant fills the through hole 16 and forms a strengthened bump 42 on the lower surface of the substrate 10, the strengthened bump 42 surrounds the chip bearing area 12 and within the field of encapsulant area 14. The strengthened bump 42 is made of a plurality of bumps with bar shape. The shape of the through hole 16 is in round shape, oval shape, polygon shape, bar shape (shown in figure), or multi-radian shape.

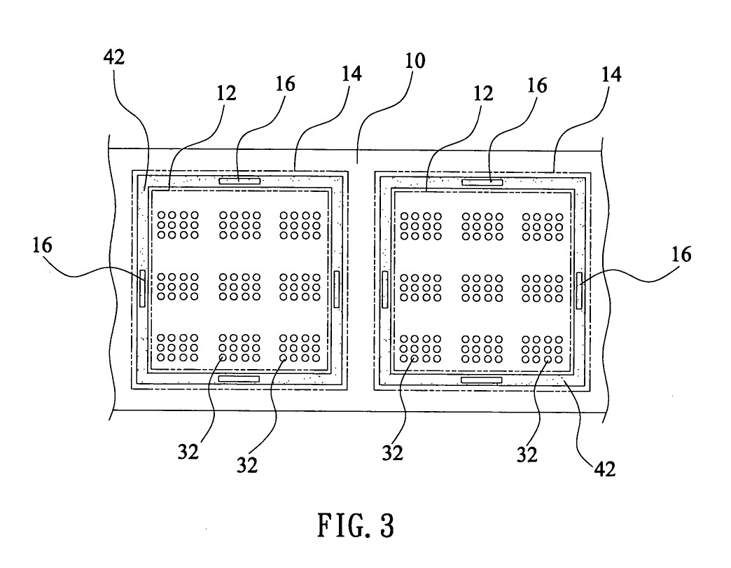

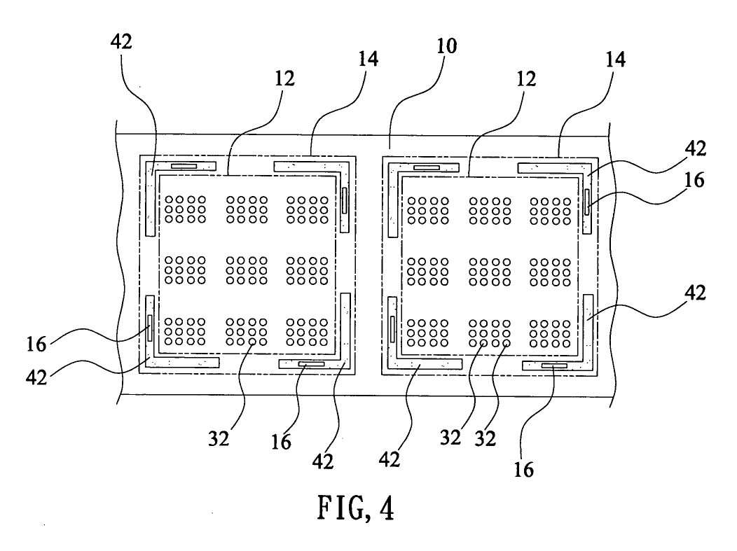

Please refer to FIG. 3 and FIG. 4, are the bottom side view diagrams of the ball grid array package structure in accordance with different embodiments of the present invention. In the embodiment which shown in FIG. 3, the strengthened bump 42 is made of those window-shaped bar bumps, and in the embodiment which shown in FIG. 4, the strengthened bump 42 is made of those L-shaped bar bumps. In the embodiments mentioned previously, the chip is arranged on the chip bearing area 12 by anyone of the fine pitch ball grid array package method, the very fine pitch ball grid array package method, the micro ball grid array package method, or the window ball grid array package method.

During the molding process of the present invention, the substrate and the chip are arranged in the cavity at the beginning, then filling the encapsulant into the cavity and covering the chip and the substrate with the encapsulant. The electrical-connecting point on the lower surface of the substrate will not be covered and each through hole was filled with the encapsulant in the cavity. Next, processing the curing process to make the encapsulant harden and take it out of the cavity after hardens. At the mean time, the encapsulant in the through hole formed a strengthened bump on the lower surface of the substrate. Eventually, mounting those conductive balls on the lower surface of the substrate to electrically connect each electrical-connecting points respectively. Therefore, the BGA package process is complete.

Accordingly, the present invention provides a strengthened bump formed by the encapsulant to enhance the mechanical strength of the substrate to reduce the warpage of the substrate efficiently during the post molding cure process, and to avoid the warpage of the substrate caused from the stress due to the temperature variation during the package process to affect the following processes. The strengthened bump is formed by the encapsulant during the molding process, the strengthened bump can be made during the existed package process and no extra process or cost needed. Furthermore, it can raise the production yield and reduce the production cost.

Although the present invention has been explained in relation to its preferred embodiment, it is to be understood that other modifications and variation can be made without departing the spirit and scope of the invention as hereafter claimed.

What is claimed is:

1. A ball grid array package structure, comprising:
a substrate, wherein an upper surface of said substrate has at least one chip bearing area, and a plurality of electrical-connecting points are arranged on a lower surface of said substrate;
a plurality of chips are arranged on said chip bearing area and electrically connected with said electrical-connecting points;
a plurality of through holes penetrating said substrate at the edge of said chip bearing area;
an encapsulant used to cover said chips and filling said through holes to form a strengthened bump surrounding said chip bearing area on said lower surface of said substrate; and
a plurality of conductive balls is respectively arranged on said electrical-connecting points.

2. A ball grid array package structure according to claim 1, wherein said substrate is made of selected from the group of polyamide, glass, aluminum oxide, epoxy, beryllium oxide, and elastomer.

3. A ball grid array package structure according to claim 1, wherein said electrical-connecting points are metal solder pads.

4. A ball grid array package structure according to claim 1, wherein the shape of said through holes is in round, oval, polygon, bar or multi-radian shape.

5. A ball grid array package structure according to claim 1, wherein said encapsulant is mainly made of epoxy.

6. A ball grid array package structure according to claim 1, wherein said strengthened bump is made of a plurality of bumps with bar shape.

7. A ball grid array package structure according to claim 1, wherein said strengthened bump is made of a plurality of L-shaped bar bumps.

8. A ball grid array package structure according to claim 1, wherein said strengthened bump is a window-shaped bar bump.

9. A ball grid array package structure according to claim 1, wherein said conductive balls are made of stannum.

10. A ball grid array package structure according to claim 1, wherein said chips are arranged on said chip bearing area by a fine pitch ball grid array package method, a very fine pitch ball grid array package method, a micro ball grid array package method, or a window ball grid array package method.
